(19) United States
(12) Patent Application Publication
(10) Pub. No.: US 2026/0101429 A1
(43) Pub. Date: Apr. 9, 2026

(54) INDUCTOR STRUCTURE WITH RING FOR TEMPERATURE COMPENSATION IN A RECEIVER ANALOG FRONT-END (RX AFE)

(71) Applicant: NVIDIA Corporation, Santa Clara, CA (US)

(72) Inventors: Wenlong Jiang, San Jose, CA (US); Shawn Wang, Campbell, CA (US); Arif Amin, Fremont, CA (US); Dai Dai, Sunnyvale, CA (US)

(21) Appl. No.: 18/909,024

(22) Filed: Oct. 8, 2024

(51) Int. Cl. H05K 1/02

(52) U.S. Cl. CPC H05K 1/0201; H05K 2201/06

(57) ABSTRACT

Technologies for providing temperature compensation in a receiver analog front-end (RX AFE) are described. One receiver device includes an RX AFE circuit with at least one load component and at least one load inductor structure with a closed ring. The RX AFE circuit is subject to circuit parameter variation across a range of temperatures that causes a temperature drift in the receiver device. The closed ring reduces the temperature drift by generating an eddy current to reduce an effective inductance of the at least one load inductor structure. The eddy current depends on an equivalent series resistance (ESR) of the closed ring.

### TECHNICAL FIELD

At least one embodiment generally pertains to communication systems, and more specifically, but not exclusively, to an inductor structure with a ring for temperature compensation in a receiver analog front-end (RX AFE).

### BACKGROUND

Communications systems transmit and receive signals at a high data rate (e.g., up to 200 Gbits/sec). High-speed transmissions exhibit significant noise attributes (e.g., due to the transmission medium) that require the use of communication devices (e.g., transmitters and receivers) configured to perform digital pre-processing by a transmitter device and post-processing by a receiver device. The variation of circuit properties across temperature cause a temperature drift which is undesirable for the stable operation of communication devices.

### BRIEF DESCRIPTION OF DRAWINGS

Various embodiments in accordance with the present disclosure will be described with reference to the drawings, in which:

FIG. 1A illustrates an example communication system with a load inductor structure with a closed ring 140, in accordance with at least some embodiments.

FIG. 1B is a block diagram of a communication system employing a load inductor structure with a closed ring 140 in a receiver device, according to at least one embodiment.

FIG. 2 is a circuit diagram of an RX AFE circuit with a Continuous-Time Linear Equalizer (CTLE) and load inductor structures according to at least one embodiment.

FIG. 3 illustrates an example load inductor structure according to at least one embodiment.

FIG. 4 is a circuit diagram an equivalent circuit representing the load inductor structure of FIG. 3 according to at least one embodiment.

FIG. 5 is a graph showing CTLE transfer function temperature drift comparison according to at least one embodiment.

FIG. 6 is a circuit diagram of an RX AFE circuit with a Variable Gain Amplifier (VGA) and a load inductor structure according to at least one embodiment.

FIG. 7 is a graph showing VGA transfer function temperature drift comparison according to at least one embodiment.

FIG. 8 is a flow diagram of a method for an initial design of a load inductor structure with a closed ring according to at least one embodiment.

FIG. 9 is a flow diagram of a method for iterating the initial design of the load inductor structure with a closed ring according to at least one embodiment.

FIG. 10 is a flow diagram of a method for manufacturing a load inductor structure with a closed ring according to at least one embodiment.

FIG. 11 illustrates an example computer system, including instructions for designing a load inductor structure with a closed ring for an RX AFE circuit, in accordance with at least some embodiments.

FIG. 12 is a block diagram of a computing system having two processing devices coupled to each other and multiple networks according to at least one embodiment.

FIG. 13 is a block diagram of a computing system having a central processing unit (CPU) and a graphics processing unit (GPU) in a single integrated circuit according to at least one embodiment.

FIG. 14 is a block diagram of a computing system having tensor core graphics processing units (GPUs) according to at least one embodiment.

### DETAILED DESCRIPTION

One type of communication interface is a serializer/deserializer (SerDes) interface. SerDes designs need to meet a temperature range requirement in certain applications, e.g., 0° C. to 105° C. for data center application or −40° C. to 125° C. for automotive application. The variation of circuit properties with temperature, such as the transconductance variation, capacitance variation, output impedance variation etc., can lead to temperature drift of a receiver analog front-end (RX AFE) transfer function. This temperature drift is undesirable for the stable operation of the receiver device. For example, a receiver device can be susceptible to RX AFE temperature drift. RX AFE temperature drift refers to the variation in performance characteristics of the analog front-end circuitry in a receiver due to temperature changes. The temperature drift can be higher than 2 dB without any compensation implementation. This temperature drift is primarily caused by the sensitivity of components like transistors, resistors, and capacitors to temperature fluctuations, which can alter their electrical properties. Additionally, thermal expansion of materials and self-heating of components during operation contribute to these performance shifts. The effects of temperature drift can include signal distortion, increased noise, gain variation, and changes in filter characteristics, all of which can degrade the overall signal integrity. Mitigating these effects involves implementing temperature compensation techniques, robust thermal management, and regular calibration to ensure consistent performance in varying temperature environments.

Conventional solutions depended on either bias current adjustments, based on temperature (i.e., bias current with temperature slope), or active compensation circuits. The active temperature compensation techniques come at the cost of area, power, linearity, or noise. For example, bias current adjustments typically come with a linearity penalty at cooler temperatures. The active compensation circuits typically increases noise and complexity, as well as circuit variability.

Aspects and embodiments of the present disclosure address the above deficiencies and others by providing a load inductor structure with a closed ring that reduces a temperature drift by generating an eddy current to reduce an effective inductance of the load inductor structure. The magnitude of these eddy currents can be influenced by the equivalent series resistance (ESR) associated with the closed ring. In various embodiments, a receiver device may include an RX AFE circuit (also referred to as RX AFE block or sub-block) that incorporates at least one load component and at least one load inductor structure with a closed ring. This RX AFE circuit can be subject to temperature variations resulting in parameter changes across different temperatures, potentially leading to temperature drift within the receiver device. To mitigate this issue, the closed ring is designed to generate eddy currents that effectively reduce the effective inductance of at least one load inductor structure.

Aspects and embodiments of the present disclosure employ a closed ring inside the inductor as a temperature compensation technique that only involves passive circuits. Aspects and embodiments of the present disclosure can be used in an empirical flow developed for an initial design and then modifications in the late design cycle for fine-tuning. Aspects and embodiments of the present disclosure are applicable to any high-speed RX AFE that already has inductors for bandwidth extension or higher boost. Aspects and embodiments of the present disclosure can limit the temperature drift of each block to be less than 1 dB or even 0.5 dB.

Aspects and embodiments of the present disclosure achieves temperature drift suppression or compensation in the RX AFE circuit through a completely passive circuit layout incorporating an inductor with an internal ring. This structure creates an eddy current via mutual coupling, which influences the effective inductance based on the ESR of the ring. With the routing metal's positive temperature coefficient, the eddy current increases in cooler temperatures and decreases in warmer temperatures, adjusting the inductance accordingly to counteract temperature drift. That is, the eddy current will be higher at lower temperatures and the eddy current will be lower at higher temperatures, meaning lower effective inductances at the lower temperatures and higher effective inductance at higher temperatures. This is typically desired for the temperature drift compensation. Aspects and embodiments of the present disclosure can achieve a notable temperature drift improvement of at least 1 dB.

Aspects and embodiments of the present disclosure can be entirely reliant on passive circuit elements, which do not suffer from the same disadvantages or additional noise seen in earlier solutions. The passive design also allows for more flexibility during the design cycle. That is, adjustments can be made late in the circuit layout process to adapt to more precise temperature drift characterization.

Aspects and embodiments of the present disclosure can be used in RX AFE circuits that need to minimize the drift across temperatures. Aspects and embodiments of the present disclosure can have an inductor layout with a shorted part of the internal traces, forming a closed ring as part of the inductor layout. The temperature drift is lower than an inductor without the closed ring. The inductor layout with the closed ring causes a mutual coupling of the closed ring with the rest of the inductor, and the closed ring has a positive temperature coefficient associated with the ESR of the closed ring. Due to the mutual coupling, the closed ring would generate an eddy current to reduce the effective inductance. Since the ESR of the closed ring has a positive temperature coefficient, the eddy current is higher at lower temperatures and lower at high temperatures, meaning lower effective inductances at lower temperatures and higher effective inductances at higher temperatures. This is typically desired for the compensation of the temperature drift. The temperature compensation scheme, as described herein, is a tradeoff with the effective inductance. The temperature compensation can be fine tuned with the ring placement inside the inductor and the width of the closed ring. The RX AFE circuit can be used in different types of front-end circuits, such as a Continuous-Time Linear Equalizer (CTLE) or a Variable Gain Amplifier (VGA).

Therefore, advantages of the receivers, systems, and methods implemented in accordance with some embodiments of the present disclosure include, but are not limited to, allowing compensation to be adjusted through an entire design cycle, providing design agility, and reducing extra circuit complexity and impairment overhead, etc. Other advantages will be apparent to those skilled in the art of signaling, as will be discussed hereinafter.

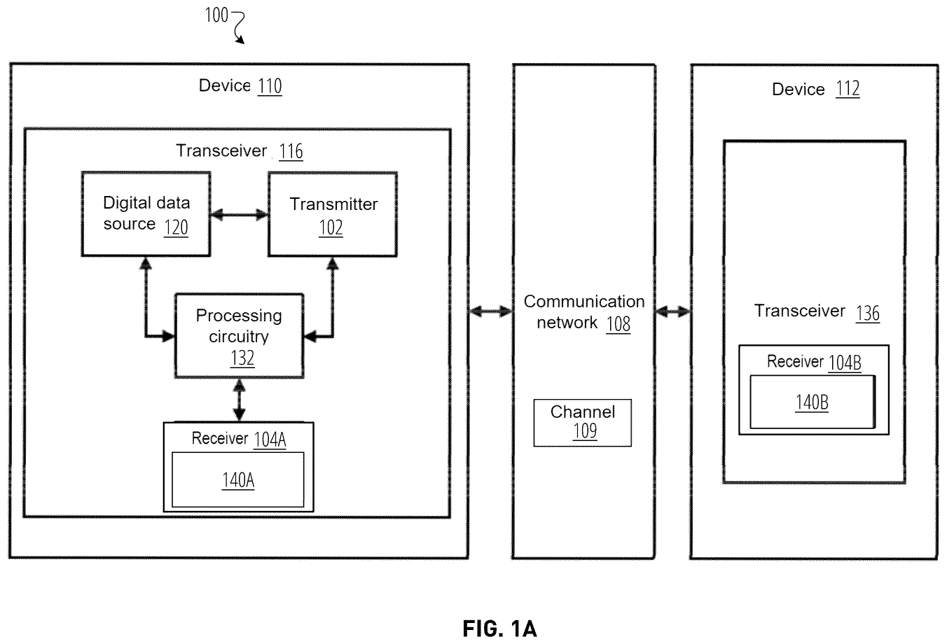

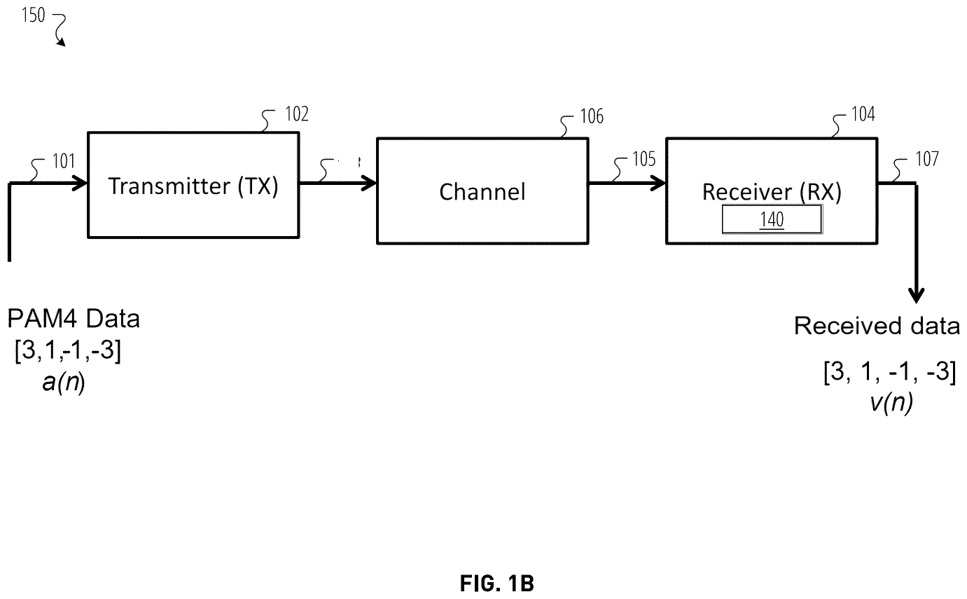

FIG. 1A illustrates an example communication system 100 with a load inductor structure with a closed ring 140, in accordance with at least some embodiments. The system 100 includes a device 110, a communication network 108 including a communication channel 109, and a device 112. In at least one example embodiment, devices 110 and 112 correspond to one or more of a Personal Computer (PC), a laptop, a tablet, a smartphone, a server, a collection of servers, or the like. In some embodiments, the devices 110 and 112 may correspond to any appropriate type of device that communicates with other devices also connected to a common type of communication network 108. According to embodiments, the receiver 104A, 104B of devices 110 or 112 may correspond to a graphics processing unit (GPU), a switch (e.g., a high-speed network switch), a network adapter, a central processing unit (CPU), a data processing unit (DPU), an NVLink switch, etc. As another specific but non-limiting example, the devices 110 and 112 may correspond to servers offering information resources, services and/or applications to user devices, client devices, or other hosts in the system 100.

Examples of the communication network 108 that may be used to connect the devices 110 and 112 include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In other embodiments, the communication network 108 can be a Peripheral Component Interconnect Express (PCIe) interconnect. PCIe is a high-speed interface standard used to connect various hardware components. It can be an interconnect for devices such as graphics cards (GPUs), solid-state drives (SSDs), network cards, and other peripherals. PCIe offers a scalable, high-speed, and point-to-point connection between devices, including CPUs, GPUs, memory, and the like. In other embodiments, the communication network 108 can be a high-speed interconnect, such as an interconnect that deploys the NVLink technology. The NVLink interconnect can be a GPU-GPU interconnect used between GPUs, a CPU-GPU interconnect between GPUs and CPUs, or an interconnect used between other devices. NVLink offers a higher bandwidth and lower latency than traditional PCIe connections, which are typically used in computing hardware. NVLink is especially useful in scenarios that require massive parallel processing, such as artificial intelligence (AI), machine learning, deep learning, high-performance computing (HPC), and data analytics. For example, in NVIDIA's DGX systems and high-end gaming or AI workstations, NVLink helps GPUs exchange data at speeds that are necessary for demanding tasks like real-time ray tracing or training neural networks. The NVLink capacity can allow more GPUs to communicate through it. In one specific, but non-limiting example, the communication network 108 is a network that enables data transmission between the devices 110 and 112 using data signals (e.g., digital, optical, wireless signals). The embodiments described herein can be utilized in a system with a high-speed, scalable switch, such as a switch using the NVSwitch technology. NVSwitch is a high-speed, scalable switch developed by NVIDIA that facilitates data communication between multiple GPUs in a system, allowing them to work together more efficiently by providing high-bandwidth, low-latency interconnections. The NVSwitch serves as a central hub or high-bandwidth fabric that interconnects all the GPUs in a system, enabling each GPU to communicate with every other GPU quickly and efficiently. The NVSwitch can be coupled between other types of devices, such as CPUs, accelerators, memory, or the like. The NVSwitch can be used for tasks requiring intense computation and collaboration between multiple GPUs, such as AI model training, scientific simulations, and large-scale data processing. The embodiments described herein can be used in a high-performance computing system, such as a computing system modeled after NVIDIA's DGX systems, which are designed specifically for artificial intelligence (AI), deep learning, and high-performance computing (HPC) workloads. DGX systems are optimized for large-scale GPU computation and parallel processing, integrating multiple GPUs, high-bandwidth interconnects, and software frameworks tailored for AI and HPC tasks. In at least one embodiment, a system for high-speed network communication includes a processing unit, a network interface comprising a receiver or transceiver with the load inductor structure with a closed ring, as described herein. The processing unit can include a CPU, a GPU, a DPU, a network adapter, a network switch, an NVLink switch, or the like.

Other examples for the communication network 108 can include other chip-to-chip or die-to-die interconnects, such as GRS, LPI (low power interface) or LLI (low latency interface).

The device 110 includes a transceiver 116 for sending and receiving signals, for example, data signals. The data signals may be digital or optical signals modulated with data or other suitable signals for carrying data. The transceiver 116 may include a digital data source 120, a transmitter 102, a receiver 104A, and processing circuitry 132 that controls the transceiver 116. The digital data source 120 may include suitable hardware and/or software for outputting data in a digital format (e.g., in binary code and/or thermometer code). The digital data output by the digital data source 120 may be retrieved from memory (not illustrated) or generated according to input (e.g., user input).

The transmitter 102 includes suitable software and/or hardware for receiving digital data from the digital data source 120 and outputting data signals according to the digital data for transmission over the communication network 108 to a receiver 104B of device 112.

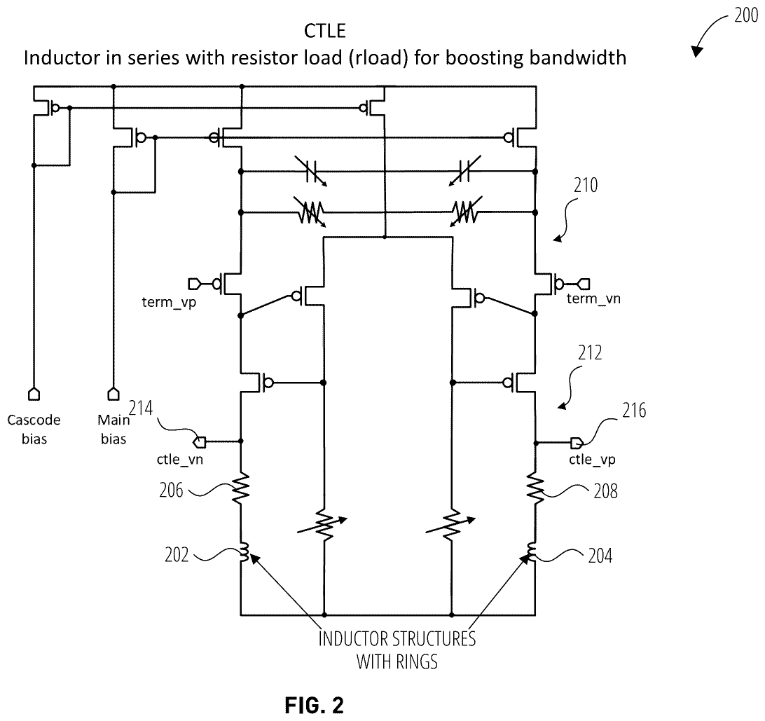

The receiver 104A, 104B of device 110 and device 112 may include suitable hardware and/or software for receiving signals, for example, data signals from the communication network 108. For example, the receivers 104A, 104B may include components for receiving processing signals to extract the data for storing in a memory. In at least one embodiment, the receiver 104B includes an RX AFE circuit having a load inductor structure with a closed ring 140B. In another embodiment, the receiver 104A also includes an RX AFE circuit having a load inductor structure with a closed ring 140A. The receiver 104B receives an incoming signal and samples the incoming signal to generate samples, such as using an analog-to-digital converter (ADC). The RX AFE circuit, including the load inductor structure with a closed ring 140B, can be coupled between a terminal or node and the ADC. Additional details of the load inductor structure with a closed ring 140 are discussed in more detail below with respect to FIG. 2.

The processing circuitry 132 may comprise software, hardware, or a combination thereof. For example, the processing circuitry 132 may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry 132 may comprise hardware, such as an application specific integrated circuit (ASIC). Other non-limiting examples of the processing circuitry 132 include an Integrated Circuit (IC) chip, a CPU, a GPU, a DPU, a microprocessor, a Field Programmable Gate Array (FPGA), a collection of logic gates or transistors, resistors, capacitors, inductors, diodes, or the like. Some or all of the processing circuitry 132 may be provided on a Printed Circuit Board (PCB) or collection of PCBs. It should be appreciated that any appropriate type of electrical component or collection of electrical components may be suitable for inclusion in the processing circuitry 132. The processing circuitry 132 may send and/or receive signals to and/or from other elements of the transceiver 116 to control the overall operation of the transceiver 116.

The transceiver 116 or selected elements of the transceiver 116 may take the form of a pluggable card or controller for the device 110. For example, the transceiver 116 or selected elements of the transceiver 116 may be implemented on a network interface card (NIC).

The device 112 may include a transceiver 136 for sending and receiving signals, for example, data signals over a channel 109 of the communication network 108. The channel 109 can be PCIe, NVLink, Ethernet, InfiniBand, Ground Reference Signal (GRS), Chip-to-Chip (C2C), Die-to-Die (D2D), or the like. The same or similar structure of the transceiver 116 may be applied to transceiver 136, and thus, the structure of transceiver 136 is not described separately.

Although not explicitly shown, it should be appreciated that devices 110 and 112 and the transceivers 116 and 136 may include other processing devices, storage devices, and/or communication interfaces generally associated with computing tasks, such as sending and receiving data.

FIG. 1B illustrates a block diagram of an example communication system 150 employing a load inductor structure with a closed ring 140 in a receiver 104, according to at least one embodiment. In the example shown in FIG. 1B, a PAM level-4 (PAM4) modulation scheme is employed with respect to the transmission of a signal (e.g., digitally encoded data) from a transmitter (TX) 102 to a receiver (RX) 104 via a communication channel 106 (e.g., a transmission medium). The communication channel 106 can be PCIe, NVLink, Ethernet, InfiniBand, GRS, C2C, D2D, or the like. In this example, the transmitter 102 receives 101 an input data (i.e., the input data at time n is represented as “a(n)”), which is modulated in accordance with a modulation scheme (e.g., PAM4) and sends the signal a(n) including a set of data symbols (e.g., symbols −3, −1, 1, 3, wherein the symbols represent coded binary data). It is noted that while the use of the PAM4 modulation scheme is described herein by way of example, other data modulation schemes can be used in accordance with embodiments of the present disclosure, including for example, a non-return-to-zero (NRZ) modulation scheme, PAM3, PAM7, PAM8, PAM16, etc. For example, for an NRZ-based system, the transmitted data symbols consist of symbols −1 and 1, with each symbol value representing a binary bit. This is also known as a PAM level-2 or PAM2 system as there are 2 unique values of transmitted symbols. Typically, a binary bit 0 is encoded as −1, and a bit 1101 is encoded as 1 as the PAM2 values.

In the example shown, the PAM4 modulation scheme uses four (4) unique values of transmitted symbols to achieve higher efficiency and performance. The four levels are denoted by symbol values −3, −1, 1, 3, with each symbol representing a corresponding unique combination of binary bits (e.g., 00, 01, 10, 11).

The communication channel 106 is a destructive medium in that the channel acts as a low pass filter which attenuates higher frequencies more than it attenuates lower frequencies, introduces inter-symbol interference (ISI) and noise from cross talk, from power supplies, from Electromagnetic Interference (EMI), or from other sources. The communication channel 106 can be over serial links (e.g., a cable, PCBs traces, copper cables, optical fibers, or the like), read channels for data storage (e.g., hard disk, flash solid-state drives (SSDs), high-speed serial links, deep space satellite communication channels, applications, or the like.

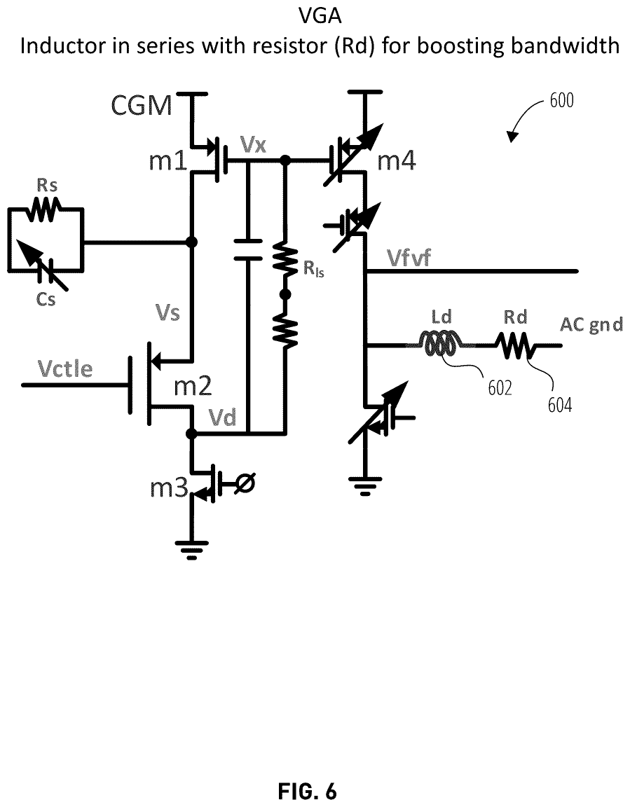

As described above, in some communication systems, the transmitter 102 sends the signal 103 as a data signal with or without a transmitter clock used to generate the data signal. The receiver (RX) 104 receives an incoming signal 105 over the communication channel 106. The incoming signal 105 can be degraded and attenuated by the communication channel 106 and include noise. The receiver 104 can output a received signal 107, “v(n),” including the set of data symbols (e.g., symbols −3, −1, 1, 3, wherein the symbols represent coded binary data). The load inductor structure with a closed ring 140 can be used to compensate for temperature drift in the receiver 104. The receiver 104 can include an RX AFE circuit, such as a Continuous-Time Linear Equalizer (CTLE) or a Variable Gain Amplifier (VGA). The load inductor structure with a closed ring 140 can be coupled in series with at least one load component (e.g., a load resistor or a load transistor) of the CTLE. Similarly, the load inductor structure with a closed ring 140 can be coupled in series with at least one load component (e.g., a load resistor or a load transistor) of the VGA. Additional details of the load inductor structure with a closed ring 140 are discussed in more detail below with respect to FIG. 2 (CTLE) and FIG. 6 (VGA).

FIG. 2 is a circuit diagram of an RX AFE circuit with a CTLE 200 and load inductor structures 202 and 204 according to at least one embodiment. CTLE 200 is a type of analog circuit used to compensate for signal degradation, particularly in high-speed communication systems. Signal degradation, such as attenuation and distortion, occurs as a signal travels through a medium (like a PCB trace, cable, or optical fiber), especially at higher frequencies. The CTLE 200 is designed to counteract these effects by providing frequency-dependent gain to the signal. The RX AFE circuit can use the load inductor structure 202 and 204 in series with the load component 206 and 208 for boosting bandwidth.

As illustrated in FIG. 2, the CTLE 200 includes differential input terminals 210 (labeled “term_vp” and “term_vn”) and differential output terminals 212 (labeled “ctle_vn” and “ctle_vp”). The CTLE 200 includes a first load component 206 coupled to a first output terminal 214 of the differential output terminals 212, and a second load component 208 coupled to a second output terminal 216 of the differential output terminals 212. As illustrated in FIG. 2, the load component 206 and the load component 208 are load resistors. In other embodiments, the load component 206 and load component 208 can be load transistors. The CTLE 200 includes a first load inductor structure 202 coupled in series with the first load component 206, and a second load inductor structure 204 coupled in series with the second load component 208.

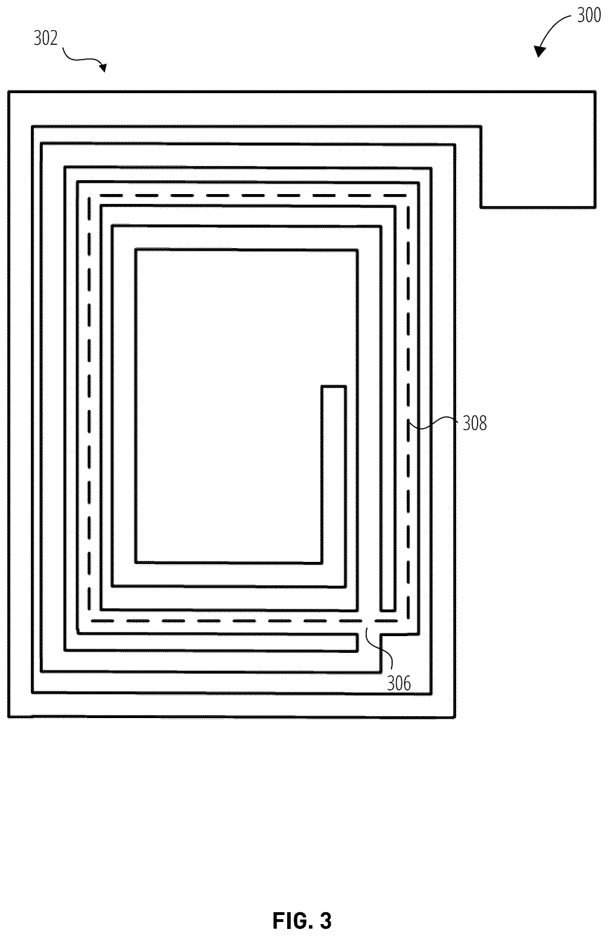

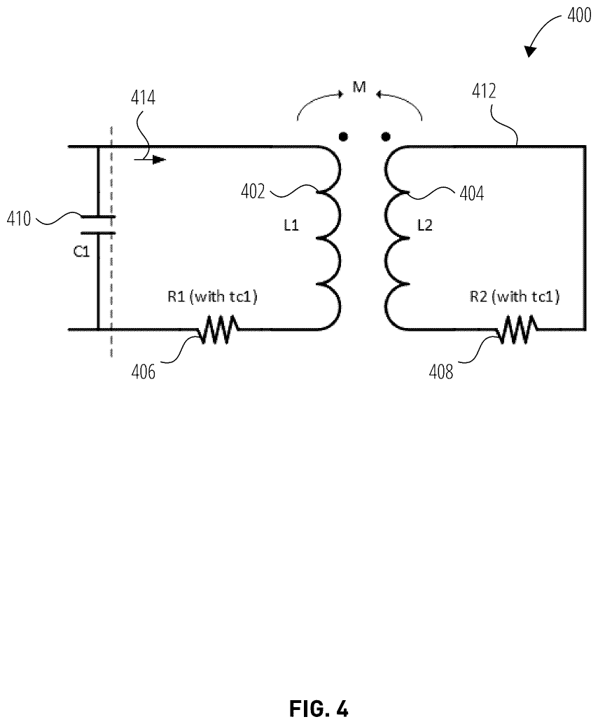

As described herein, the RX AFE circuit can be subject to circuit parameter variation across a range of temperatures that causes a temperature drift in the RX AFE circuit. The load inductor structure 202 and load inductor structure 204 can each include a closed ring. The closed ring can reduce the temperature drift by generating an eddy current to reduce an effective inductance of the load inductor structure 202 and load inductor structure 204. The magnitudes of the eddy currents depends on an equivalent series resistance (ESR) of the closed rings of the load inductor structure 202 and load inductor structure 204. In at least one embodiment, the load inductor structure 202 (or load inductor structure 204) include a set of one or more turns with at least one turn being shorted to form the closed ring. In at least one embodiment, the load inductor structure 202 (or load inductor structure 204) is a conductive trace structure in a PCB or an integrated circuit process. The load inductor structure 202 (or load inductor structure 204) can be implemented as a PCB inductor (also referred to as a planar inductor). A PCB inductor is defined by its physical structure, including trace pattern, trace width, spacing, and the use of layers. Similarly, an inductor in an IC is also defined by its physical structure, including trace pattern, trace width, spacing, and the use of layers. Changing the physical dimensions of these elements alters the inductance, resistance, and parasitic properties of the inductor. By carefully adjusting these parameters, designers can tailor the inductor to meet specific performance requirements, balancing factors such as inductance value, Q-factor, footprint, and frequency response. In at least one embodiment, the load inductor structure 202 (or load inductor structure 204) includes a couple of dimensions that are used to design it for specific frequency values, specific inductance values, needed for a particular design. In at least one embodiment, the load inductor structure 202 (or load inductor structure 204) can include a size based on a specified inductance value and a location of the closed ring based on a specified temperature compensation value. The closed ring can include a trace width based on a specified frequency value. Additional details of the load inductor structure 202 (and load inductor structure 204) are described below with respect to FIG. 3, FIG. 4, and FIG. 6. An example of the load inductor structure 202 (or load inductor structure 204) is illustrated and described in more detail below.

Although FIG. 2 illustrates a differential CTLE, in another embodiment, the CTLE 200 can be a single-ended CTLE. In this embodiment, the CTLE 200 includes a single-ended input terminal and a single-ended output terminal. A load component, such as load component 206 (load resistor or load transistor) is coupled to the single-ended output terminal. A load inductor structure, such as load inductor structure 202, is coupled in series with the load component 206.

FIG. 3 illustrates an example load inductor structure 300 according to at least one embodiment. The load inductor structure 300 can be the load inductor structure with a closed ring 140 of FIG. 1. The load inductor structure 300 can be the load inductor structure 202 or the load inductor structure 204 of FIG. 2. As described above, the physical structure of the load inductor structure 300 can be implemented as a PCB inductor (also referred to as planar inductor), such as illustrated in FIG. 3. Alternatively, the load inductor structure 300 can be implemented as conductive traces on one or more layers of an integrated circuit (IC). The conductive traces can be designed as a spiral or loop trace on one more layers of the IC or PCB. The spiral or loop trace can have one or more “turns.” In the context of an inductor coil implemented in an IC or PCB, a “turn” refers to a single complete loop of the conductive trace that forms the coil. In some cases, the turns can be defined fractionally according to the changes in direction, such as when a turn does not form a complete loop. In ICs and PCBs, inductors are typically implemented as planar spiral coils. The “turns” of an inductor coil are designed using conductive traces (usually copper or aluminum) that are laid out on one or more layers of the substrate. The design and arrangement of these turns affect the inductance and the performance of the inductor. In a single-layer design, the inductor coil includes multiple turns of a conductive trace arranged in a flat, spiral pattern on a single layer. The spiral is either circular or square-shaped to maximize space efficiency. The trace starts at the center of the spiral and loops outward. In some cases, inductors may span multiple layers of the PCB or IC using vias (vertical interconnects) to connect the layers. This allows for a more compact design and can increase the total inductance by increasing the number of turns without consuming additional horizontal space. The number of turns in the spiral coil directly affects the inductance. More turns generally increase inductance but also increase resistance due to the longer trace length. Spacing between adjacent turns can also affect the characteristics of the inductor. If the turns are too close, parasitic capacitance between turns can increase, which can degrade the performance of the inductor, especially at higher frequencies. The width of the trace and the distance between turns are often optimized for the target frequency and required inductance. The load inductor structure 300 can include a set of one or more turns. One of the turns is shorted at a shorting point 306 to form a closed ring 308.

As described above, the physical dimensions of the physical structure of load inductor structure 300, including trace pattern, trace width, spacing, and the use of layers, can be changed to alter the inductance, resistance, and parasitic properties of the load inductor structure 300. More specifically, the spiral or loop traces (i.e., turns) is typically formed by routing a copper trace in a spiral or loop pattern on an IC layer. The number of turns in the spiral and the spacing between them are key factors in determining the inductance. The trace width, spacing between turns, and the overall area covered by the spiral are carefully controlled to achieve the desired inductance value. Inductors can be implemented on a single layer or across multiple layers of the IC or PCB. Multilayer designs can increase inductance by stacking spirals on top of each other, connected via vias (i.e., vertical interconnects). The PCB material, typically FR4 or a high-frequency substrate like Rogers, influences the inductance due to its dielectric properties. The thickness of the substrate between layers also affects the coupling between turns or layers. Adding more turns increases the inductance, as the magnetic field generated by each turn adds constructively to the total magnetic flux. However, this also increases the series resistance of the inductor, which can affect Q-factor and introduce more losses. Reducing the number of turns decreases the inductance and may reduce the resistance, improving the Q-factor but potentially leading to insufficient inductance for the intended application. Increasing the width of the trace reduces the direct current (DC) resistance of the inductor, which can improve the Q-factor and reduce power losses. However, wider traces also reduce the inductance slightly because they decrease the density of the turns. Narrower traces increase the inductance slightly but at the cost of higher resistance, which can degrade the performance of the inductor at high frequencies due to increased losses. Increasing the spacing between turns reduces the mutual inductance between adjacent turns, lowering the overall inductance. This can be useful to reduce coupling with nearby components or traces but may require more area. Reducing the spacing increases the inductance by enhancing the coupling between adjacent turns. However, it also increases the risk of capacitive coupling between turns, which can cause parasitic capacitance and affect high-frequency performance. The inductor area can also be modified according to the desired design. Expanding the area of the spiral (increasing the outer diameter) increases the inductance because the magnetic field lines have a larger loop to circulate, which increases the total flux. However, this also increases the size of the inductor, which might be impractical for space-constrained designs. Reducing the area decreases the inductance, making the component more compact but potentially less effective in the intended application. Using multiple layers connected by vias can significantly increase the inductance without expanding the footprint. This is because the magnetic fields from the stacked layers add together. However, this also increases the complexity of the design and the potential for increased parasitic capacitance and interlayer coupling. Fewer layers reduce the inductance but also simplify the design and can reduce parasitic effects. Increasing the substrate thickness between layers in a multilayer can reduce the coupling between layers, slightly decreasing inductance. It can also increase the effective inductance if the magnetic flux extends through a larger volume. A higher dielectric constant in the substrate can increase the parasitic capacitance between turns, which might lower the self-resonant frequency of the inductor.

In addition to the physical dimensions described above, there are some physical dimensions or attributes of the load inductor structure 300 that can be selected for the closed ring 308. In particular, the placement of the closed ring 308 can be based on a specified temperature compensation value. The placement of the closed ring 308 be modified by changing a location of the shorting point 306 to any one of the turns 302. The closed ring 308 can have a trace width. The trace width of the closed ring 308 can be based on a specified frequency value. The load inductor structure 300 can be represented as an equivalent circuit diagram as illustrated and described below with respect to FIG. 4.

FIG. 4 is a circuit diagram an equivalent circuit 400 representing the load inductor structure 300 of FIG. 3 according to at least one embodiment. The equivalent circuit 400 is a simplified representation of an actual electrical circuit that captures the essential behavior of the load inductor structure 300 using idealized components. This diagram uses basic electrical elements like resistors, capacitors, inductors, voltage sources, and current sources as a model of the real circuit's behavior under specific conditions. An inductor structure typically includes an inductance (L), a capacitance (C), and a resistance (R). The equivalent circuit 400, representing the load inductor structure 300, has one turn shorted, forming an inductor structure with a first inductor 402, a first resistor 406, and a capacitor 410, and a closed loop 412 (i.e., closed ring 308) with a second inductor 404 and a second resistor 408. The first inductor 402 represents the set of one or more turns 302 of FIG. 3, and the second inductor 404 represents the closed ring 308 of FIG. 3. The first inductor 402 includes a first inductance (L1), and the second inductor 404 includes a second inductance (L2). There is a mutual coupling of the first inductor 402 and the second inductor 404, as described herein. The first inductor 402 is coupled in series with the first resistor 406, having a first resistance (R1). The second inductor 404 is coupled in series with the second resistor 408, having a second resistance (R2). The first inductor 402 and first resistor 406 are coupled in parallel with the capacitor 410. During operation, a first current 414 flowing through the first inductor 402 induces an induced current 416 in the closed loop 412. The following is an example scrip for the equivalent inductance and impedance of the equivalent circuit 400. For the example, the following example values are used: L1=820e−12; L2=21.6e−12; M=82.2e−12; C1=6.93=15; T=125; Tbase=−40; R1=14.2*(1+0.0045*(T−Tbase)); R2:1.4*(1+0.0045*(T−Tbase));
freq=100e6:100e6:100e9;
Omega=2.3.1415*freq % The ratio of the induced current in secondary coil to the % current in the primary coil (inductance+resistance section) i2_over_i1=-li*omega*M./(li*omega*L2+R2);
% The induced voltage at the primary coil due to the induced % current at the secondary coil
v1_l2induced=li*omega. *M. *i2_over_i1;
% check the equivalent impedance of the overall transformer % except C1
L1_ind_impedance=li*omega*L1+vl_l2induced+R1; %L1_ind_impedance=li*omega*L1+R1;
% The impedance of C1 L1_cap_impedance=1./(*li*omega*C1);
% Calculate the overall impedance L1_total_impedance=L1_ind_impedance. *L1_cap_impedance./(L1_ind_impedance+L1_cap_impedance);
% Calculate the apparent effective inductance appar_ind=imag(L1_total_impedance)./omega;

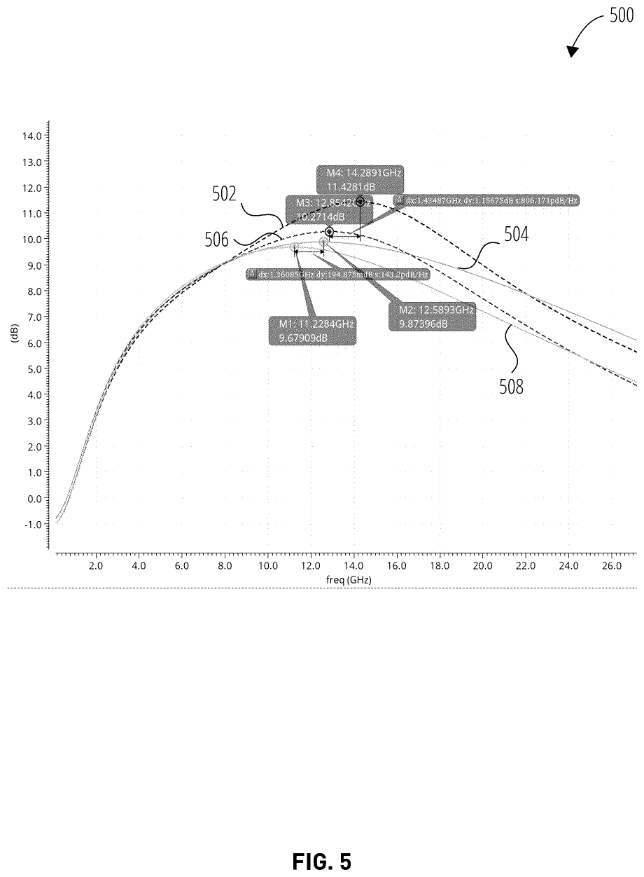

The example script can be used to simulate the equivalent circuit 400 to compare the CTLE transfer function temperature drift, such as illustrated in the graph of FIG. 5.

FIG. 5 is a graph 500 showing CTLE transfer function temperature drift comparison according to at least one embodiment. The graph 500 shows a first transfer function 502 for a CTLE without the load inductor structure with a closed ring at a first temperature (e.g., −40 C) and a second transfer function 504 for a CTLE with the load inductor structure with a closed ring at the first temperature. The graph 500 shows a third transfer function 506 for a CTLE without the load inductor structure with a closed ring at a second temperature (e.g., 125 C) and a fourth transfer function 508 for a CTLE with the load inductor structure with a closed ring at the second temperature. As illustrated in FIG. 5, the temperature drift can be reduced from 1.2 dB to 0.2 dB using the load inductor structure with the closed ring. Alternatively, the load inductor structure with the closed ring can achieve other amounts of reduction in temperature drift.

FIG. 6 is a circuit diagram of an RX AFE circuit with a VGA 600 and a load inductor structure 602 according to at least one embodiment. In many AFE circuits, the incoming signal strength can vary significantly due to factors like distance, interference, or environmental conditions. The VGA 600 helps manage these variations by adjusting the gain in real-time, ensuring that the output signal maintains a consistent amplitude suitable for further processing. The VGA 600 is an electronic amplifier that can adjust its gain dynamically, which means it can amplify input signals by different amounts based on control inputs. The VGA 600 allows the gain (amplification factor) of an analog signal to be adjusted electronically, which is essential for maintaining signal integrity across varying signal strengths and conditions. The VGA 600 can be part of an Automatic Gain Control (AGC) loop. The AGC circuit dynamically adjusts the VGA's gain to maintain a constant output level, even as the input signal varies. By optimizing the gain, the VGA 600 can help maintain a high signal-to-noise ratio (SNR). If the signal is too weak, increasing the gain can help amplify it above the noise floor. Conversely, if the signal is too strong, reducing the gain prevents distortion and saturation of subsequent stages in the AFE. The VGA 600 can be designed with either linear or logarithmic gain control characteristics, where Linear VGAs adjust the gain in a linear fashion, meaning that a linear change in the control signal results in a linear change in gain, and Logarithmic VGAs adjust the gain on a logarithmic scale, which is useful in applications where the signal level varies exponentially. The gain of a VGA 600 can be controlled either by an analog control voltage (analog-controlled VGA) or by digital signals (digitally-controlled VGA, also known as a digital Variable Gain Amplifier or DVGA). Analog-controlled VGAs offer continuous gain adjustment, while digital VGAs provide discrete steps of gain adjustment. In an AFE circuit, the VGA 600 is typically positioned after the initial low-noise amplifier (LNA) and any necessary filtering stages. The VGA 600 can adjust the signal level before it is sent to the analog-to-digital converter (ADC). By adjusting the signal level, the VGA 600 ensures that the ADC operates within its optimal input range, avoiding clipping or underutilization of the ADC's dynamic range. The RX AFE circuit can use the load inductor structure 602 in series with a load component 604 (e.g., load resistor or load transistor) for boosting bandwidth.

As illustrated in FIG. 6, the VGA 600 includes an input terminal (labeled “Vctle”) and an output terminal (labeled “Vfvf”). The VGA 600 includes a load component 604 coupled in series with the load inductor structure 602 and an AC ground (labeled “AC gnd”). As illustrated in FIG. 6, the load component 604 is a load resistor. In other embodiments, the load component 604 is a load transistor.

As described herein, the RX AFE circuit can be subject to circuit parameter variation across a range of temperatures that causes a temperature drift in the RX AFE circuit. The load inductor structure 602 can include a closed ring. The closed ring can reduce the temperature drift by generating an eddy current to reduce an effective inductance of the load inductor structure 602. The magnitudes of the eddy currents depends on an ESR of the closed rings of the load inductor structure 602. In at least one embodiment, the load inductor structure 602 includes a set of one or more turns with at least one turn being shorted to form the closed ring. In at least one embodiment, the load inductor structure 602 is a conductive trace structure in a PCB or an integrated circuit process. The load inductor structure 602 can be implemented as a PCB inductor (also referred to as a planar inductor). Alternatively, the load inductor structure 602 can be implemented in one or more layers of an IC. In at least one embodiment, the load inductor structure 602 includes a couple of dimensions that are used to design it for specific frequency values, specific inductance values, needed for a particular design. In at least one embodiment, the load inductor structure 602 can include a size based on a specified inductance value and a location of the closed ring based on a specified temperature compensation value. The closed ring can include a trace width based on a specified frequency value. An example of the load inductor structure 602 is illustrated and described above with respect to FIG. 3.

Although FIG. 6 illustrates a single-ended VGA, in another embodiment, the VGA 600 can be a differential VGA. In this embodiment, the VGA 600 includes differential input terminals and differential output terminals. A load component, such as load component 604 (load resistor or load transistor) is coupled to each of the differential output terminals.

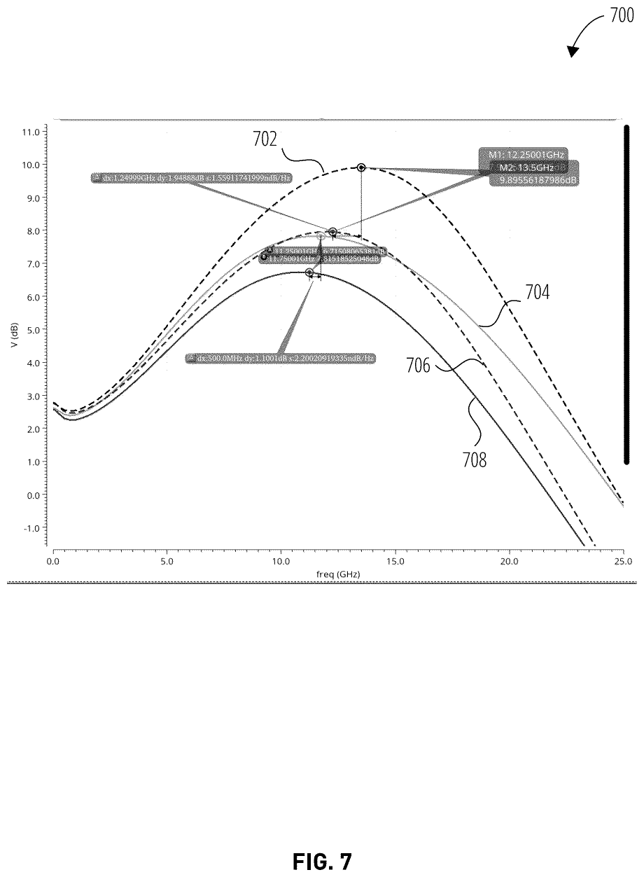

FIG. 7 is a graph 700 showing VGA transfer function temperature drift comparison according to at least one embodiment. The graph 700 shows a first transfer function 702 for a VGA without the load inductor structure with a closed ring at a first temperature (e.g., −40 C) and a second transfer function 704 for a VGA with the load inductor structure with a closed ring at the first temperature. The graph 700 shows a third transfer function 706 for a VGA without the load inductor structure with a closed ring at a second temperature (e.g., 125 C) and a fourth transfer function 708 for a VGA with the load inductor structure with a closed ring at the second temperature. As illustrated in FIG. 7, the temperature drift can be reduced from 1.95 db to 1.1 dB using the load inductor structure with the closed ring. Alternatively, the load inductor structure with the closed ring can achieve other amounts of reduction in temperature drift.

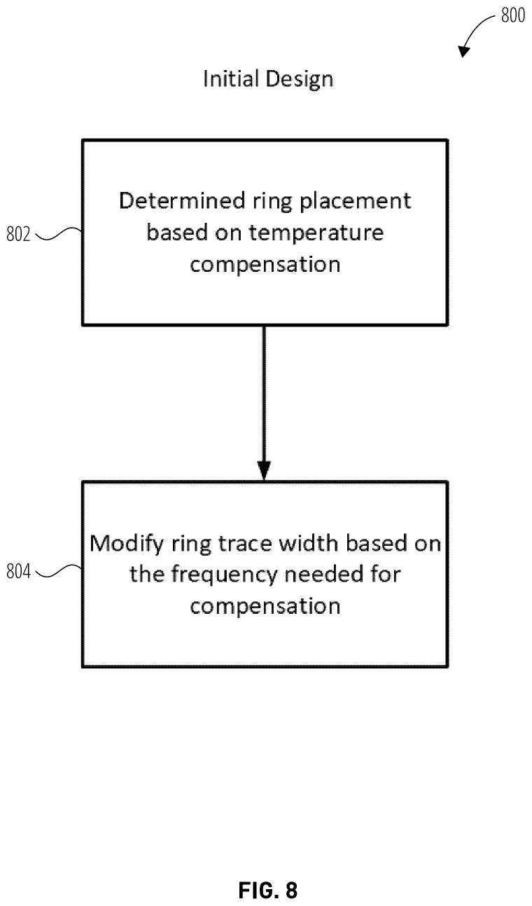

FIG. 8 is a flow diagram of a method 800 for an initial design of a load inductor structure with a closed ring according to at least one embodiment. The method 800 can be performed by processing logic comprising hardware, software, firmware, or any combination thereof. For example, the method 800 can be performed by a computing system, having one or more processing device and one or more computer readable storage medium. The method 800 can be implemented as instructions stored in the one or more computer readable storage medium that, when executed by the one or more processing devices can perform the operations of the method 800. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible. In at least one embodiment, the method 800 is performed manually.

In at least one embodiment, method 800 may be performed by multiple processing threads, each thread executing one or more individual functions, routines, subroutines, or operations of the method. In at least one embodiment, processing threads implementing method 800 may be synchronized (e.g., using semaphores, critical sections, and/or other thread synchronization logic). Alternatively, processing threads implementing method 800 may be executed asynchronously with respect to each other. Various operations of method 800 may be performed differently than the order shown in FIG. 8. Some operations of the methods may be performed concurrently with other operations. In at least one embodiment, one or more operations shown in FIG. 8 may not always be performed.

Referring to FIG. 8, the processing logic begins with the processing logic determining a closed ring placement based on a temperature compensation (block 802). The processing logic modifies the ring trace width of the closed ring based on a frequency needed for compensation. (block 804).

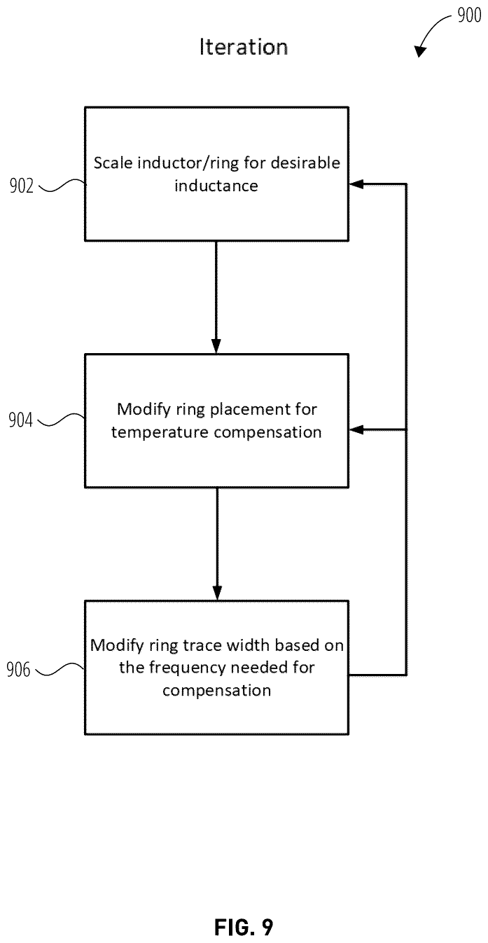

FIG. 9 is a flow diagram of a method 900 for iterating the initial design of the load inductor structure with a closed ring according to at least one embodiment. The method 900 can be performed by processing logic comprising hardware, software, firmware, or any combination thereof. For example, the method 900 can be performed by a computing system, having one or more processing device and one or more computer readable storage medium. The method 900 can be implemented as instructions stored in the one or more computer readable storage medium that, when executed by the one or more processing devices can perform the operations of the method 900. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In at least one embodiment, method 900 may be performed by multiple processing threads, each thread executing one or more individual functions, routines, subroutines, or operations of the method. In at least one embodiment, processing threads implementing method 900 may be synchronized (e.g., using semaphores, critical sections, and/or other thread synchronization logic). Alternatively, processing threads implementing method 900 may be executed asynchronously with respect to each other. Various operations of method 900 may be performed differently than the order shown in FIG. 9. Some operations of the methods may be performed concurrently with other operations. In at least one embodiment, one or more operations shown in FIG. 9 may not always be performed.

Referring to FIG. 9, the processing logic begins with the processing logic scaling an inductor structure with the closed ring to a specified inductance (block 902). The processing logic can modify ring placement for temperature compensation (block 904). The processing logic can modify the ring trace width based on the frequency needed for compensation (block 906). The processing logic can repeat the operations at blocks 902, 904, and 906 over multiple iterations to achieve a desired load inductor structure with the closed ring.

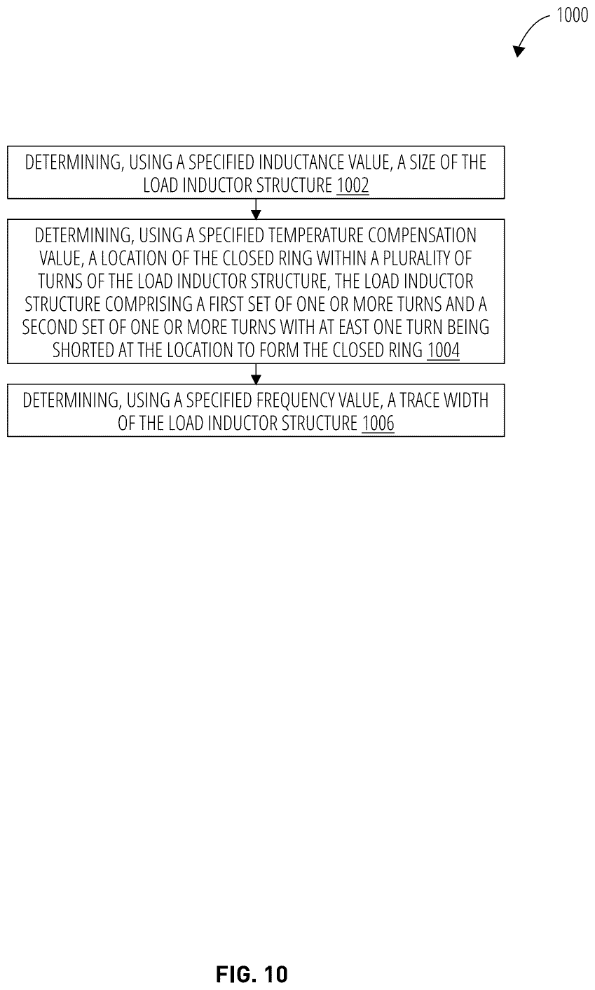

FIG. 10 is a flow diagram of a method 1000 for designing or manufacturing a load inductor structure with a closed ring according to at least one embodiment. The method 1000 can be performed by processing logic comprising hardware, software, firmware, or any combination thereof. For example, the method 1000 can be performed by a computing system, having one or more processing device and one or more computer readable storage medium. The method 1000 can be implemented as instructions stored in the one or more computer readable storage medium that, when executed by the one or more processing devices can perform the operations of the method 1000. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In at least one embodiment, method 1000 may be performed by multiple processing threads, each thread executing one or more individual functions, routines, subroutines, or operations of the method. In at least one embodiment, processing threads implementing method 1000 may be synchronized (e.g., using semaphores, critical sections, and/or other thread synchronization logic). Alternatively, processing threads implementing method 1000 may be executed asynchronously with respect to each other. Various operations of method 1000 may be performed differently than the order shown in FIG. 10. Some operations of the methods may be performed concurrently with other operations. In at least one embodiment, one or more operations shown in FIG. 10 may not always be performed.

Referring to FIG. 10, the processing logic begins with the processing logic determining, using a specified inductance value, a size of the load inductor structure. At block 1004, the processing logic determines, using a specified temperature compensation value, a location of the closed ring within a plurality of turns of the load inductor structure. The load inductor structure includes a set of one or more turns with at least one turn being shorted at the location to form the closed ring. At block 1006, the processing logic determines, using a specified frequency value, a trace width of the load inductor structure.

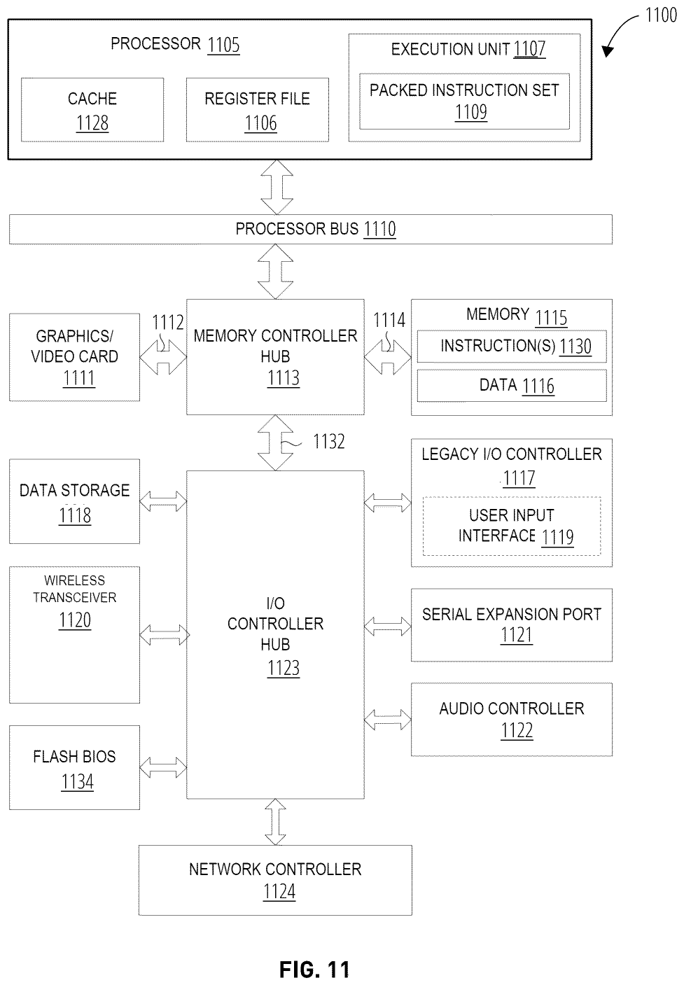

FIG. 11 illustrates an example computer system 1100, including instructions for designing a load inductor structure with a closed ring 140 for an RX AFE circuit, in accordance with at least some embodiments. In at least one embodiment, computer system 1100 may be a system with interconnected devices and components, a System on Chip (SoC), or some combination. In at least one embodiment, computer system 1100 is formed with a processor 1105 that may include execution units to execute an instruction. In at least one embodiment, computer system 1100 may include, without limitation, a component, such as a processor 1105, to employ execution units including logic to perform algorithms for processing data. In at least one embodiment, computer system 1100 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1100 may execute a version of WINDOWS′ operating system available from Microsoft Corporation of Redmond, Wash., although other operating systems (UNIX and Linux, for example), embedded software, and/or graphical user interfaces, may also be used.

In at least one embodiment, computer system 1100 may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, computer system 1100 may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

In at least one embodiment, computer system 1100 may include, without limitation, processor 1105 that may include, without limitation, one or more execution units 1107 that may be configured to execute a Compute Unified Device Architecture (“CUDA”) (CUDA® is developed by NVIDIA Corporation of Santa Clara, CA) program. In at least one embodiment, a CUDA program is at least a portion of a software application written in a CUDA programming language. In at least one embodiment, computer system 1100 is a single processor desktop or server system. In at least one embodiment, computer system 1100 may be a multiprocessor system. In at least one embodiment, processor 1105 may include, without limitation, a CISC microprocessor, a RISC microprocessor, a VLIW microprocessor, and a processor implementing a combination of instruction sets, or any other processor device, such as a digital signal processor, for example. In at least one embodiment, processor 1105 may be coupled to a processor bus 1110 that may transmit data signals between processor 1105 and other components in computer system 1100.

In at least one embodiment, processor 1105 may include, without limitation, a Level 1102 (“L1”) internal cache memory (“cache”) 1128. In at least one embodiment, processor 1105 may have a single internal cache or multiple levels of internal cache. In at least one embodiment, cache memory may reside external to processor 1105. In at least one embodiment, processor 1105 may also include a combination of both internal and external caches. In at least one embodiment, a register file 1106 may store different types of data in various registers including, without limitation, integer registers, floating point registers, status registers, and instruction pointer register.

In at least one embodiment, execution unit 1107, including, without limitation, logic to perform integer and floating point operations, also resides in processor 1105. Processor 1105 may also include a microcode (“ucode”) read only memory (“ROM”) that stores microcode for certain macro instructions. In at least one embodiment, execution unit 1107 may include logic to handle a packed instruction set 1109. In at least one embodiment, by including packed instruction set 1109 in an instruction set of a general-purpose processor 1105, along with associated circuitry to execute instructions, operations used by many multimedia applications may be performed using packed data in a general-purpose processor 1105. In at least one embodiment, many multimedia applications may be accelerated and executed more efficiently by using full width of a processor's data bus for performing operations on packed data, which may eliminate a need to transfer smaller units of data across a processor's data bus to perform one or more operations one data element at a time.

In at least one embodiment, execution unit 1107 may also be used in microcontrollers, embedded processors, graphics devices, DSPs, and other types of logic circuits. In at least one embodiment, computer system 1100 may include, without limitation, a memory 1115. In at least one embodiment, memory 1115 may be implemented as a Dynamic Random Access Memory (DRAM) device, a Static Random Access Memory (SRAM) device, flash memory device, or other memory devices. Memory 1115 may store instruction(s) 1130 and/or data 1116 represented by data signals that may be executed by processor 1105.

In at least one embodiment, a system logic chip may be coupled to a processor bus 1110 and memory 1115. In at least one embodiment, the system logic chip may include, without limitation, a memory controller hub (“MCH”) 1113, and processor 1105 may communicate with MCH 1113 via processor bus 1110. In at least one embodiment, MCH 1113 may provide a high bandwidth memory path 1114 to memory 1115 for instruction and data storage and for storage of graphics commands, data, and textures. In at least one embodiment, MCH 1113 may direct data signals between processor 1105, memory 1115, and other components in computer system 1100 and may bridge data signals between processor bus 1110, memory 1115, and a system I/O 1132. In at least one embodiment, a system logic chip may provide a graphics port for coupling to a graphics controller. In at least one embodiment, MCH 1113 may be coupled to memory 1115 through high bandwidth memory path 1114, and graphics/video card 1111 may be coupled to MCH 1113 through an Accelerated Graphics Port (“AGP”) interconnect 1112.

In at least one embodiment, computer system 1100 may use system I/O 1132 that is a proprietary hub interface bus to couple MCH 1113 to I/O controller hub (“ICH”) 1123. In at least one embodiment, ICH 1123 may provide direct connections to some I/O devices via a local I/O bus. In at least one embodiment, a local I/O bus may include, without limitation, a high-speed I/O bus for connecting peripherals to memory 1115, a chipset, and processor 1105. Examples may include, without limitation, an audio controller 1122, a firmware hub (“flash BIOS”) 1134, a wireless transceiver 1120, a data storage 1118, a legacy I/O controller 1117 containing a user input interface 1119, a keyboard interface, a serial expansion port 1121, such as a USB, and a network controller 1124. Data storage 1118 may comprise a hard disk drive, a floppy disk drive, a CD-ROM device, a flash memory device, or other mass storage device.

In at least one embodiment, FIG. 11 illustrates a system, which includes interconnected hardware devices or “chips.” In at least one embodiment, FIG. 11 may illustrate an example SoC. In at least one embodiment, devices illustrated in FIG. 11 may be interconnected with proprietary interconnects, standardized interconnects (e.g., PCIe), or some combination thereof. In at least one embodiment, one or more components of system 1104 are interconnected using compute express link (“CXL”) interconnects.

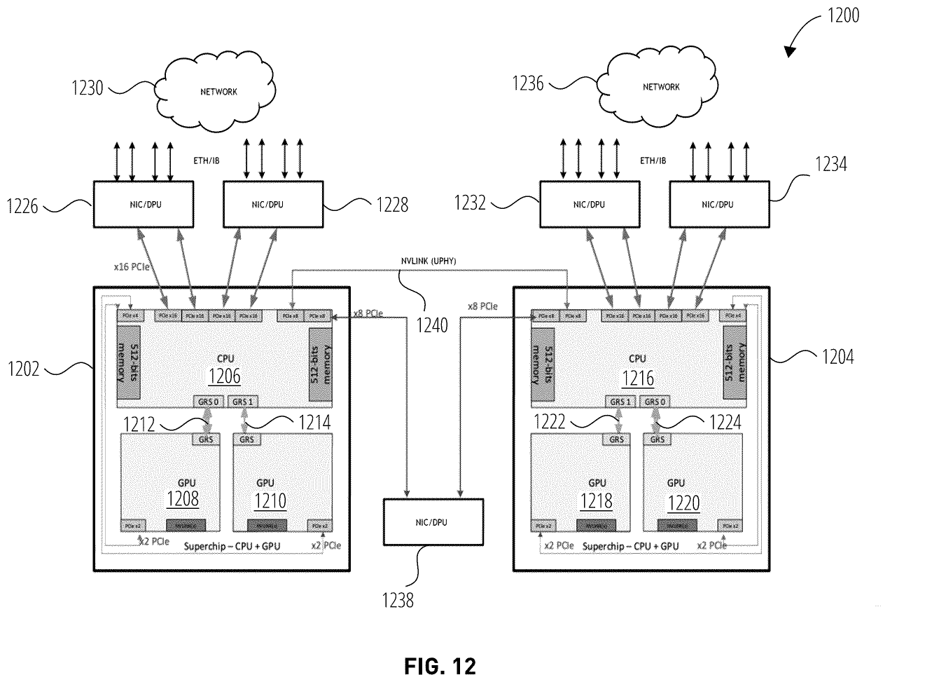

FIG. 12 is a block diagram of a computing system 1200 having two processing devices coupled to each other and multiple networks according to at least one embodiment. The computing system 1200 is designed with multiple integrated circuits (referred to as processing devices), where each integrated circuit includes a CPU and two GPUs, forming a powerful and flexible architecture. These processing devices are interconnected via an NVLink (or other high-speed interconnect), enabling high-speed communication between the processing devices, and are also connected through a Network Interface Card (NIC) or Data Processing Unit (DPU) to ensure efficient data transfer across the computing system 1200. The coupling of processing devices through NVLink allows for seamless data exchange and parallel processing, enhancing overall computational performance. Additionally, these processing devices are connected to multiple networks through one or more network interface cards (NICs) or DPUs, enabling the system to handle complex, multi-network tasks with high bandwidth and low latency. This configuration makes the computing system digital data source 120 highly suitable for demanding applications that require significant processing power, such as artificial intelligence (AI), machine learning (ML), and data-intensive computing, while ensuring robust connectivity and scalability across various networked environments. The integrated circuits of the computing system 1200 can include one or more CPUs and one or more GPUs. An example architecture of a multi-GPU architecture is illustrated in FIG. 12.

As illustrated in FIG. 12, the computing system 1200 includes a processing device 1202 with a multi-GPU architecture. In particular, the processing device 1202 includes a CPU 1206, a GPU 1208, and a GPU 1210. The CPU 1206 can be coupled to the GPU 1208 via an die-to-die (D2D) or chip-to-chip (C2C) interconnect 1212, such as a Ground-Referenced Signaling interconnect (GRS interconnect). The CPU 1206 can be coupled to the GPU 1210 via a D2D or C2C interconnect 1214. The CPU 1206 can also couple to the GPU 1208 and GPU 1210 via PCIe interconnects. The CPU 1206 can be coupled to one or more network interface cards (NICs) or data processing units (DPUs), which are coupled to one or more networks. For example, as illustrated in FIG. 12, the CPU 1206 is coupled to a first NIC/DPU 1226, which is coupled to a network 1230. The CPU 1206 is also coupled to a second NIC/DPU 1228, which is coupled to the network 1230. The NIC/DPU 1226 and NIC/DPU 1228 can be coupled to the network 1230 over Ethernet (ETH), NVLINK or InfiniBand (IB) connections.

The computing system 1200 also includes a processing device 1204 with a multi-GPU architecture. In particular, the processing device 1204 includes a CPU 1216, a GPU 1218, and a GPU 1220. The CPU 1216 can be coupled to the GPU 1218 via an D2D or C2C interconnect 1222. The CPU 1216 can be coupled to the GPU 1220 via a D2D or C2C interconnect 1224.

The CPU 1216 can also couple to the GPU 1218 and GPU 1220 via PCIe interconnects. The CPU 1216 can be coupled to one or more NICs or DPUs, which are coupled to one or more networks. For example, as illustrated in FIG. 12, the CPU 1216 is coupled to a first NIC/DPU 1232, which is coupled to a network 1236. The CPU 1216 is also coupled to a second NIC/DPU 1234, which is coupled to the network 1236. The NIC/DPU 1232 and NIC/DPU 1234 can be coupled to the network 1236 over Ethernet (ETH), NVLINK or InfiniBand (IB) connections.

In at least one embodiment, the processing device 1202 and the processing device 1204 can communication with each other via a NIC/DPU 1238, such as over PCIe interconnects. The processing device 1202 and processing device 1204 can also communicate with each other over a high-bandwidth communication interconnects 1240, such as an NVLink interconnect or other high-speed interconnects.

The computing system 1200 includes various types of interconnects. Each of the interconnects includes various RX AFE circuits (also referred to as RX AFE sub-blocks). These RX AFE circuits can include the load inductor structures, as described herein.

In at least one embodiment, the RX AFE circuit is part of a Serializer/Deserializer circuit (SerDes circuit). The SerDes circuit can be a transceiver that converts parallel data to serial data and vice versa. SerDes circuits can facilitate transmission between two devices over serial streams, reducing the number of data paths, wires/traces, terminals, etc. SerDes circuits can include one or more RX AFE circuits, which are coupled between terminals and analog-to-digital converters (ADC) of the SerDes circuit. The SerDes circuit can also include other components, such as a clock-recovery circuit, equalization blocks, symbol detectors. In at least one embodiment, the clock-recovery circuit includes a feedback loop with a phase detector, a filter, and a controlled oscillator (CO) in a closed feedback loop. The CO can be a digitally-controlled oscillator (DCO), a voltage-controlled oscillator (VCO), or the like, as described herein. The ADC generates samples of an incoming data signal. The equalization block can determine current data based on the samples and provides an equalization output. The equalization output can be used by the phase detector to determine the phase information. The phase detector can measure a phase offset corresponding to the current data. The filter can filter the phase offset and control the CO based on the filtered phase offset.

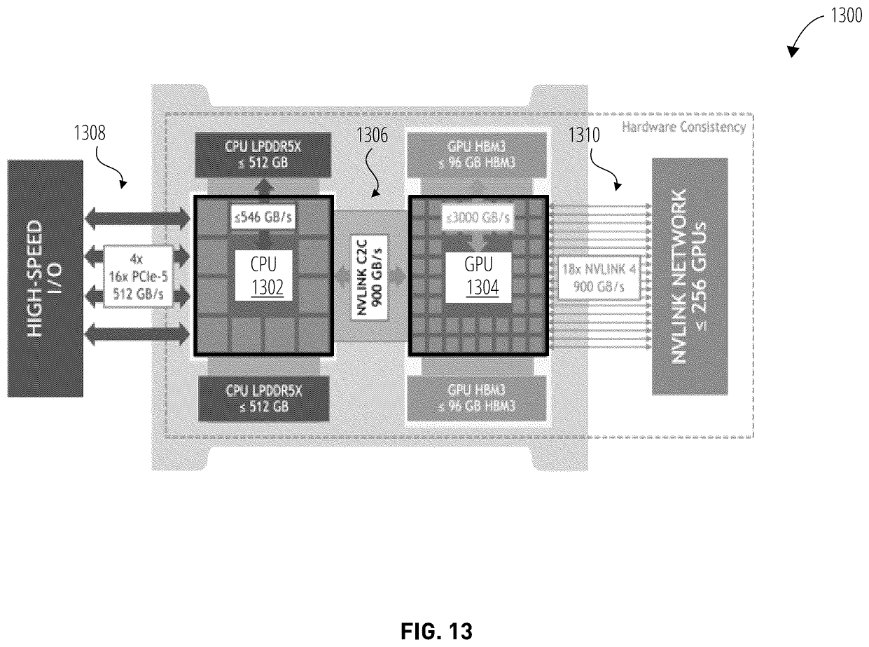

FIG. 13 is a block diagram of a computing system 1300 having a CPU 1302 and a GPU 1304 in a single integrated circuit according to at least one embodiment. The computing system 1300 can be a highly integrated design where a CPU 1302 and GPU 1304 are connected on a single integrated circuit, utilizing an NVLink C2C (Chip-to-Chip) interconnect 1306 to enable fast, low-latency communication between the two processing units. This close integration allows for efficient data transfer and parallel processing between the CPU 1302 and GPU 1304, optimizing performance for complex computational tasks. The GPU elements within the computing system 1300 can be interconnected using an NVLink network, allowing for scalability up to 256 GPU elements, creating a powerful, unified processing environment ideal for large-scale AI, ML, and high-performance computing applications. The NVLink network can be a GPU fabric of high-bandwidth communication interconnects 1310. Additionally, the computing system 1300 can be designed to interface with a high-speed I/O through PCIe interconnects 1308, ensuring rapid data transfer to and from external devices, further enhancing the system's capabilities in handling data-intensive tasks and providing robust connectivity to peripheral components. It should be noted that the C2C interconnects 1306 can be considered D2D interconnects since the CPU 1302 and the GPU 1304 are located on the same integrated circuit. The integrated circuit can include CPU memory (also referred to as main memory) and GPU memory, which are accessible by the CPU 1302 and the GPU 1304, respectively, over high-speed interconnects. The computing system 1300 can bring together performance of the GPU 1304 with the versatility of the CPU 1302. The CPU 1302 can be connected with a high-bandwidth and memory coherent C2C interconnects 1306 in a single integrated circuit. The computing system 1300 can support a link switch system.

The computing system 1300 includes various types of interconnects. Each of the interconnects includes various RX AFE circuits (also referred to as RX AFE sub-blocks). These RX AFE circuits can include the load inductor structures, as described herein.

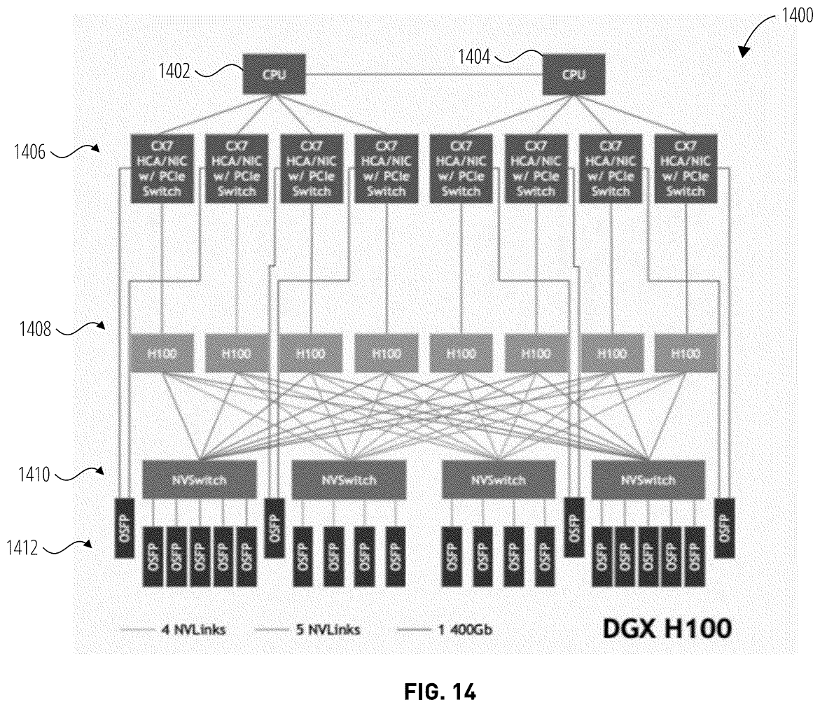

FIG. 14 is a block diagram of a computing system 1400 having tensor core GPUs 1408 according to at least one embodiment. The computing system 1400 can be a DBX H100 system, which is a high-performance computing platform designed to meet the demands of AI, ML, and deep learning (DL) workloads. The computing system 1400 can include multiple tensor core GPUs 1408 (e.g., NVIDIA H100 Tensor Core GPUs). The tensor core GPUs 1408 can each be one of the integrated circuits described above with respect to FIG. 13. The tensor core GPUs 1408 can be optimized for AI/ML/DL applications, offering exceptional performance for deep learning training, inference, and high-performance computing tasks. The tensor core GPUs 1408 within the computing system 1400 are interconnected using high-speed communication interfaces like NVLinks, enabling rapid data transfer between them, which is crucial for handling large-scale AI models and datasets with low latency. This computing system 1400 is designed for scalability, allowing for the integration of additional GPUs as required, making it versatile enough for research, development, and deployment in data centers for production AI workloads. Each GPU is equipped with Tensor Cores, specialized processing units that accelerate matrix operations, a fundamental component of AI and deep learning algorithms. These Tensor Cores enable the system to perform mixed-precision calculations efficiently, balancing speed and accuracy. Given the power consumption and heat generation of multiple tensor core GPUs 1408, the computing system 1400 can include advanced cooling solutions and power management features to ensure safe operation while maintaining peak performance. It is supported by a comprehensive software ecosystem, including NVIDIA's CUDA programming model, AI frameworks like TensorFlow and PyTorch, and other HPC and AI software tools, which enable developers and researchers to harness the full power of the tensor core GPUs 1408 for their specific applications. The computing system 1400 is ideally suited for large-scale AI model training, real-time inference, scientific simulations, data analytics, and other compute-intensive tasks that require massive parallel processing power.

The tensor core GPUs 1408 can be coupled to multiple CPUs, such as CPU 1402 and CPU 1404, using switches 1406 (e.g., CX7 HCA/NIC with PCIe switch). The tensor core GPUs 1408 can be coupled to each other via switches 1410 (e.g., NVSwitches). The switches 1406 and switches 1410 can be coupled to high-speed transceiver modules 1412. The high-speed transceiver modules 1412 can be Octal Small Form-factor Pluggable (OSFP) modules. OSFP modules refer to high-speed transceiver modules designed for rapid data communication, particularly in environments requiring significant bandwidth, such as data centers and high-performance computing systems. These modules support extremely high data rates, typically up to 400 Gbps per module, with future capabilities extending to 800 Gbps or more. OSFP modules interface with the system via the PCIe interface, enabling fast and efficient data transfer between the integrated CPU-GPU components and external networks or other connected systems. Their hot-pluggable nature allows for easy insertion or removal without the need to power down the system, offering flexibility and ease of maintenance, which is crucial in critical-uptime environments. Additionally, OSFP modules are designed for high density, maximizing the number of high-speed connections within limited space, such as in densely packed server racks. By adhering to the latest networking standards, OSFP modules ensure the computing system 1400 remains capable of meeting increasing data demands and can be upgraded to support future advancements in network speeds, thus contributing to the system's overall performance and scalability.

In at least one embodiment, the computing system 1400 can be considered a data-network configuration with full-bandwidth intra-server NVLinks. In this example, all eight tensor core GPUs 1408 can simultaneously saturate eighteen NVLinks to other GPUs within the server. The bandwidth is limited by over-subscription from multiple other GPUs. In another embodiments, data-network configuration can be a half-bandwidth intra-server NVLinks. In this example, all eight tensor core GPUs 1408 can half-subscribe eighteen NVLinks to GPUs in other servers. Four tensor core GPUs 1408 can saturate eighteen NVLinks to GPUs in other servers. This is equivalent of full-bandwidth on AllReduce with Scalable Hierarchical Aggregation and Reduction Protocol (SHARP). The reduction in all-2-all (All2All) bandwidth is a balance with server complexity and costs. In at least one embodiment, all eight tensor core GPUs 1408 can independently transfer data, using Remote Direct Memory Access (RDMA) protocol, over its own dedicated switch (e.g., 400 Gb/s HCA/NIC) in a multi-rail InfiniBand/Ethernet configuration. In this example, 800 GBps of aggregate full-duplex to non-NVLink network devices.

The computing system 1400 includes various types of interconnects. Each of the interconnects includes various RX AFE circuits (also referred to as RX AFE sub-blocks). These RX AFE circuits can include the load inductor structures, as described herein.

Other variations are within the scope of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. In at least one embodiment, the use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B and C,” unless specifically stated otherwise or otherwise clearly contradicted by context, is otherwise understood with the context as used in general to present that an item, term, etc., may be either A or B or C, or any nonempty subset of the set of A and B and C. For instance, in an illustrative example of a set having three members, conjunctive phrases “at least one of A, B, and C” and “at least one of A, B and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of the code, while multiple non-transitory computer-readable storage media collectively store all of the code. In at least one embodiment, executable instructions are executed such that different instructions are executed by different processors.

Accordingly, in at least one embodiment, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of the disclosure, and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, the terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still cooperate or interact with each other.

Unless specifically stated otherwise, it may be appreciated that throughout specification terms such as “processing,” “computing,” “calculating,” “determining,” or like, refer to actions and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transform that electronic data into other electronic data that may be stored in registers and/or memory. As non-limiting examples, a “processor” may be a network device or a MACsec device. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or parallel, continuously, or intermittently. In at least one embodiment, the terms “system” and “method” are used herein interchangeably as far as the system may embody one or more methods, and methods may be considered a system.

In the present document, references may be made to obtaining, acquiring, receiving, or inputting analog or digital data into a sub-system, computer system, or computer-implemented machine. In at least one embodiment, the process of obtaining, acquiring, receiving, or inputting analog and digital data can be accomplished in a variety of ways, such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface, or an inter-process communication mechanism.

Although descriptions herein set forth example embodiments of described techniques, other architectures may be used to implement described functionality, and are intended to be within the scope of this disclosure. Furthermore, although specific distributions of responsibilities may be defined above for purposes of description, various functions and responsibilities might be distributed and divided in different ways, depending on circumstances.

Furthermore, although the subject matter has been described in language specific to structural features and/or methodological acts, it is to be understood that the subject matter claimed in appended claims is not necessarily limited to specific features or acts described. Rather, specific features and acts are disclosed as exemplary forms of implementing the claims.

What is claimed is:

1. A receiver device comprising:
a receiver analog front-end (RX AFE) circuit comprising at least one load component and at least one load inductor structure with a closed ring, wherein the RX AFE circuit is subject to circuit parameter variation across a range of temperatures that causes a temperature drift in the receiver device, wherein the closed ring is to reduce the temperature drift by generating an eddy current to reduce an effective inductance of the at least one load inductor structure, the eddy current depending on an equivalent series resistance (ESR) of the closed ring.

2. The receiver device of claim 1, wherein the at least one load inductor structure comprises a set of one or more turns with at least one turn being shorted to form the closed ring.

3. The receiver device of claim 2, wherein the at least one load inductor structure comprises is a conductive trace structure in one or more layers of an integrated circuit comprising the receiver device.

4. The receiver device of claim 3, wherein:
the at least one load inductor structure comprises a size based on a specified inductance value;
a location of the closed ring is based on a specified temperature compensation value; and
the closed ring comprises a trace width based on a specified frequency value.

5. The receiver device of claim 1, wherein the RX AFE circuit is a Continuous-Time Linear Equalizer (CTLE), wherein the at least one load inductor structure is coupled in series with the at least one load component of the CTLE.

6. The receiver device of claim 5, wherein:
the CTLE comprises differential input terminals and differential output terminals;
the at least one load component comprises:
a first load component coupled to a first output terminal of the differential output terminals; and
a second load component coupled to a second output terminal of the differential output terminals; and
the at least one load inductor structure comprises:
a first load inductor structure coupled in series with the first load component; and
a second load inductor structure coupled in series with the second load component.

7. The receiver device of claim 5, wherein:
the CTLE comprises a single-ended input terminal and a single-ended output terminal;
the at least one load component comprises:
a first load component coupled to the single-ended output terminal; and
the at least one load inductor structure comprises:
a first load inductor structure coupled to the first load component.

8. The receiver device of claim 1, wherein the RX AFE circuit is a Variable Gain Amplifier (VGA), wherein the at least one load inductor structure is coupled in series with the at least one load component of the VGA.

9. The receiver device of claim 8, wherein:
the VGA comprises a single-ended input terminal and a single-ended output terminal;
the at least one load component comprises:
a first load component coupled to the single-ended input terminal; and
the at least one load inductor structure comprises:
a first load inductor structure coupled to the first load component.

10. The receiver device of claim 8, wherein:
the VGA comprises differential input terminals and differential output terminals;
the at least one load component comprises:
a first load component coupled to a first output terminal of the differential output terminals; and
a second load component coupled to a second output terminal of the differential output terminals; and
the at least one load inductor structure comprises:
a first load inductor structure coupled to the first load component; and
a second load inductor structure coupled to the second load component.

11. A Serializer/Deserializer (SerDes) circuit comprising:
a serializer;
a deserializer; and
a receiver comprising an analog front-end (AFE) circuit comprising at least one load inductor structure with a closed ring, wherein the AFE circuit is subject to circuit parameter variation across a range of temperatures that causes a temperature drift in the SerDes circuit, wherein the closed ring is to reduce the temperature drift by generating an eddy current to reduce an effective inductance of the at least one load inductor structure, the eddy current depending on an equivalent series resistance (ESR) of the closed ring.

12. The SerDes circuit of claim 11, wherein the at least one load inductor structure comprises a set of one or more turns with at least one turn being shorted to form the closed ring.

13. The SerDes circuit of claim 12, wherein the at least one load inductor structure comprises is a conductive trace structure in one or more layers of an integrated circuit comprising the SerDes circuit.

14. The SerDes circuit of claim 11, wherein the AFE circuit is a Continuous-Time Linear Equalizer (CTLE), wherein the at least one load inductor structure is coupled in series with the at least one load component of the CTLE.

15. The SerDes circuit of claim 14, wherein:
the CTLE comprises differential input terminals and differential output terminals;
the at least one load component comprises:
a first load component coupled to a first output terminal of the differential output terminals; and
a second load component coupled to a second output terminal of the differential output terminals; and
the at least one load inductor structure comprises:
a first load inductor structure coupled to the first load component; and
a second load inductor structure coupled to the second load component.

16. The SerDes circuit of claim 14, wherein:
the CTLE comprises a single-ended input terminal and a single-ended output terminal;
the at least one load component comprises:
a first load component coupled to the single-ended output terminal; and
the at least one load inductor structure comprises:
a first load inductor structure coupled to the first load component.

17. The SerDes circuit of claim 11, wherein the AFE circuit is a Variable Gain Amplifier (VGA), wherein the at least one load inductor structure is coupled in series with the at least one load component of the VGA.

18. The SerDes circuit of claim 17, wherein:
the VGA comprises a single-ended input terminal and a single-ended output terminal;
the at least one load component comprises:
a first load component coupled to the single-ended input terminal; and
the at least one load inductor structure comprises:
a first load inductor structure coupled to the first load component.

19. The SerDes circuit of claim 17, wherein:
the VGA comprises differential input terminals and differential output terminals;
the at least one load component comprises:
a first load component coupled to a first output terminal of the differential output terminals; and
a second load component coupled to a second output terminal of the differential output terminals; and
the at least one load inductor structure comprises:
a first load inductor structure coupled to the first load component; and
a second load inductor structure coupled to the second load component.

20. A method of designing a load inductor structure with a closed ring in an analog front-end (AFE) circuit, the method comprising:
determining, using a specified inductance value, a size of the load inductor structure;
determining, using a specified temperature compensation value, a location of the closed ring within a plurality of turns of the load inductor structure, the load inductor structure comprising a set of one or more turns with at least one turn being shorted at the location to form the closed ring; and
determining, using a specified frequency value, a trace width of the closed ring.

21. A system for high-speed network communication, the system comprising:
a processing unit; and
a network interface coupled to the processing unit, wherein the network interface comprises a receiver device comprising:
a receiver analog front-end (RX AFE) circuit comprising at least one load component and at least one load inductor structure with a closed ring, wherein the RX AFE circuit is subject to circuit parameter variation across a range of temperatures that causes a temperature drift in the receiver device, wherein the closed ring is to reduce the temperature drift by generating an eddy current to reduce an effective inductance of the at least one load inductor structure, the eddy current depending on an equivalent series resistance (ESR) of the closed ring.

22. The system of claim 21, wherein the processing unit comprises at least one of a central processing unit (CPU), a graphics processing unit (GPU), a data processing unit (DPU), a network adapter, a network switch, or an NVLink switch.
